(19) United States
(12) Patent Application Publication
(10) Pub. No.: US 2025/0304803 A1
(43) Pub. Date: Oct. 2, 2025

(54) COMPOSITION, FILM, DISPLAY PANEL, AND DISPLAY DEVICE

(71) Applicant: Shenzhen China Star Optoelectronics Semiconductor Display Technology Co., Ltd., Shenzhen (CN)

(72) Inventors: Chengxiao SUN, Shenzhen (CN); Aibing BAO, Shenzhen (CN); Miao DUAN, Shenzhen (CN); Qinfu ZHU, Shenzhen (CN); Miao ZHOU, Shenzhen (CN); Lixuan CHEN, Shenzhen (CN); Zhida XU, Shenzhen (CN); Zhiming ZHAN, Shenzhen (CN)

(73) Assignee: Shenzhen China Star Optoelectronics Semiconductor Display Technology Co., Ltd., Shenzhen (CN)

(21) Appl. No.: 19/093,246

(22) Filed: Mar. 27, 2025

(30) Foreign Application Priority Data
Mar. 29, 2024 (CN) 202410382693.9

(51) Int. Cl. C09D 7/62; C09D 4/06; C09D 7/20; C09D 7/40; C09D 133/04; C09D 135/02; C09D 163/00; G02F 1/13357; H10K 59/80

(52) U.S. Cl. CPC C09D 7/62; C09D 4/06; C09D 7/20; C09D 7/67; C09D 7/68; C09D 7/69; C09D 7/70; C09D 133/04; C09D 135/02; C09D 163/00; G02F 1/133603; G02F 1/133606; H10K 59/877

(57) ABSTRACT

Disclosed are a composition, a film, a display panel, and a display device. The composition includes, in parts by mass, 50 to 100 parts of a resin matrix; 20 to 100 parts of a multifunctional reactive monomer; 1 to 10 parts of an initiator, 5 to 30 parts of scattering particles; 100 to 500 parts of a solvent; and 1 to 10 parts of an adjuvant. Surfaces of the scattering particles are grafted with a modifying agent. The composition is carried out thermal curing and/or photocuring to prepare a film used as a diffusion layer of the display panel.

### CROSS-REFERENCE TO RELATED APPLICATIONS

This application claims priority to Chinese Patent Application No. 202410382693.9, filed on Mar. 29, 2024, the entire disclosures of which are incorporated herein by reference.

### TECHNICAL FIELD

The present disclosure relates to the field of display technology, and more particularly, to a composition, a film, a display panel, and a display device.

### BACKGROUND

In recent years, the proportion of large-sized display panels in the terminal market is gradually increasing. When the size of the display panel is increased, an increased range of viewing angle may be provided for the user, resulting in chromaticity deviation of the display panel due to the large viewing angle.

As an example of the liquid crystal display panel, the liquid crystal may be deflected by angles relative to the normal direction of the panel under different grayscales, and when light at different angles enters the liquid crystal, phase retardation (Δnd) are different, so that the brightness viewing angles under different grayscales are different, resulting in a relatively serious chromaticity deviation at a large viewing angle. At present, the chromaticity deviation phenomenon is improved by means of pixel design (e.g., multi-domain pixel structure), driving adjustment, and the like. However, the improvement of the chromaticity deviation by existing methods causes the transmittance and/or resolution to be reduced, and these methods are complicated and provide limited improvement effect.

### SUMMARY

Embodiments of the present disclosure provide a composition, a film, a display panel, and a display device, which can improve the chromaticity deviation at a large viewing angle in the display panel.

According to a first aspect, embodiments of the present disclosure provide a composition including, in parts by mass:
50 to 100 parts of a resin matrix;
20 to 100 parts of a multifunctional reactive monomer;
1 to 10 parts of an initiator;
5 to 30 parts of scattering particles;
100 to 500 parts of a solvent; and
1 to 10 parts of an adjuvant.

Surfaces of the scattering particles are grafted with a modifying agent having a structure represented by a general formula (I):

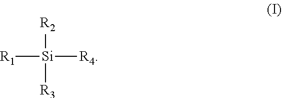

In the general formula (I), R₁ to R₃ are each independently selected from a C1-C30 alkoxy group, a halogen group,

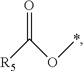

or a combination thereof.

R₄ is selected from a C1-C30 chain hydrocarbyl group unsubstituted or substituted by at least one substituent, a cyclohydrocarbyl group having 3 to 30 ring atoms and unsubstituted or substituted by at least one substituent, an aryl group having 6 to 30 ring atoms and unsubstituted or substituted by at least one substituent, a heteroaryl group having 5 to 30 ring atoms and unsubstituted or substituted by at least one substituent, an epoxy group,

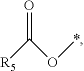

—NR₆R₇, or a combination thereof. The at least one substituent is at each occurrence selected from deuterium, a C1-C10 chain hydrocarbyl group, a C1-C10 chain hydrocarbyloxy group, a halogen group, a hydroxyl group, or a carboxyl group. R₅ is at each occurrence selected from a C1-C30 chain hydrocarbyl group. R₆ and R₇ are each independently selected from hydrogen, deuterium, a C1-C10 chain hydrocarbyl group, a C1-C10 chain hydrocarbyloxy group, an aryl group having 6 to 14 ring atoms, a heteroaryl group having 5 to 14 ring atoms, or a combination thereof.

According to a second aspect, the present disclosure provides a film prepared by subjecting the composition as described in the first aspect to a thermal curing treatment and/or a photocuring treatment.

According to a third aspect, the present disclosure provides a display panel including:
a light emitting element layer having a light-input side and a light-output side opposite to each other; and
a wide view film disposed at the light-output side of the light emitting element layer.

The wide view film includes a diffusion layer which is the film as described in the second aspect.

According to a fourth aspect, the present disclosure provides a display device including:
a display panel as described in the third aspect; and
a backlight source disposed at the light-input side of the light emitting element layer in the display panel.

### BRIEF DESCRIPTION OF THE DRAWINGS

In order to clearly explain the technical solutions in the embodiments of the present disclosure, the accompanying drawings required for the description of the embodiments are illustrated below. It will be apparent that the accompanying drawings in the following description are merely some of the embodiments of the present disclosure, and other drawings may be made to those skilled in the art based on these accompanying drawings without involving any inventive effort.

FIG. 1 is a schematic diagram of a film according to some embodiments of the present disclosure.

FIG. 2 is a schematic diagram of a first structure of a display panel according to some embodiments of the present disclosure.

FIG. 3 is a schematic diagram of a second structure of a display panel according to some embodiments of the present disclosure.

FIG. 4 is a schematic diagram of a third structure of a display panel according to some embodiments of the present disclosure.

FIG. 5 is a schematic diagram of a light emitting element layer according to some embodiments of the present disclosure.

FIG. 6 is a schematic diagram of a display device according to some embodiments of the present disclosure.

FIG. 7 shows an infrared spectrum of modified mesoporous SiO₂ particles according to Material Examples 1 and 7 of the present disclosure.

FIG. 8 shows thermogravimetric analysis graphs of modified mesoporous SiO₂ particles in Material Examples 1 and 7 of the present disclosure.

FIG. 9 shows scanning electron microscope photographs of modified mesoporous SiO₂ particles in Material Example 1.

FIG. 10 shows scanning electron microscope photographs illustrating a microscopic morphology of a surface and a cross section of a film in Material Example 1, in which (a) illustrates the surface of the film, and (b) illustrates the cross-section of the film.

### LIST OF REFERENCE NUMERALS

1: Film, 10: Display panel, 11: Resin portion, 20: Backlight source, 100: Display device, 101: Light emitting element layer, 102: First polarizer, 103: Wide view film, 104: Polarizer film, 105: Compensation film, 1012: Second polarizer, 1013: Array substrate, 1014: Liquid crystal layer, 1015: Color film substrate, 1016: Light-input side, 1011: Light-output side, 1031: Base layer, 1032: Adhesive layer, 1033: Diffusion layer.

### DETAILED DESCRIPTION

Embodiments of the present disclosure will be described with reference to the accompanying drawings. It will be apparent that the described embodiments are only a part, not all of the embodiments of the present disclosure. All other embodiments obtained by a person skilled in the art based on the embodiments in the present disclosure without involving any inventive effort fall within the scope of the present disclosure.

Unless defined otherwise, all professional and scientific terms used herein have the same meaning as those familiar to those skilled in the art. In addition, any methods and materials similar or identical to those described herein can be applied to the present disclosure. The preferred embodiments and materials described herein are exemplary only, but are not intended to limit the present disclosure.

It is to be noted that the order in which the following embodiments are described is not intended to be a definition on the preferred order of the embodiments. Various embodiments of the present disclosure may be presented in a range format. It is to be understood that the description in range format is merely for convenience and brevity and should not be construed as an inflexible limitation on the scope of the disclosure. Accordingly, the description of a range is to be considered to have specifically disclosed all the possible subranges as well as individual numerical values within that range. For example, description of a range such as from 1 to 6 is to be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range. Whenever a numerical range is indicated herein, it is meant to include any cited numeral (fractional or integral) within the indicated range.

The terms “comprises”, “comprising”, “includes”, “including”, “having” and their conjugates mean “including but not limited to”.

The term “at least one of” refers to one or more, and “multiple” or “a plurality of” refers to two or more. The term “at least one of” or the like, refers to any combination of related listed items, including any single related listed item or any combination of multiple related listed items. For example, “at least one of a, b, or c” or “at least one of a, b, and c” may all mean a, b, c, a+b (i.e., a and b), a+c, b+c, or a+b+c, in which a, b, and c respectively may be single or multiple.

The term “and/or” involve in a selection that includes any one of two or more related listed items, as well as a combination of any and all of related listed items, which includes a combination of any two related listed items, a combination of any more than two related listed items, or a combination of all related listed items. For example, “A and/or B” includes three parallel schemes, A, B, and A+B. For another example, “A, and/or, B, and/or, C, and/or, D” includes technical schemes, for example, any one of A, B, C, and D (i.e., the technical solutions by connection of “logic OR”), and combinations of any and all of A, B, C, and D, including combinations of any two or any three of A, B, C, and D, and a combination of four of A, B, C, and D (i.e., the technical solutions by connection of “logic AND”).

The term “particle size” refers to the diameter of the particle.

The term “chain hydrocarbyl” refers to an aliphatic linear hydrocarbyl group or an aliphatic branched hydrocarbyl group. “C1-C30 chain hydrocarbyl group” may be, for example, a linear alkyl group having 1 to 30 carbon atoms, a linear alkenyl group having 2 to 30 carbon atoms, a linear alkynyl group having 2 to 30 carbon atoms, a branched alkyl group having 3 to 30 carbon atoms, a branched alkenyl group having 4 to 30 carbon atoms, or a branched alkynyl group having 4 to 30 carbon atoms. The number of carbon atoms of the chain hydrocarbyl group may be, for example, 1 to 5, 2 to 8, 3 to 10, 4 to 10, 5 to 10, 5 to 15, 5 to 20, 10 to 20, or 20 to 30, for example, 1, 3, 5, 8, 10, 15, 20, 30, or a value between any two of the foregoing values. Suitable examples include, but are not limited to, methyl, ethyl, ethenyl, n-propyl, isopropyl, n-butyl, sec-butyl, tert-butyl, isobutyl, 2-ethylbutyl, 3,3-dimethylbutyl, n-pentyl, isopentyl, neopentyl, tert-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-tert-butylcyclohexyl, n-heptyl, 1-methylheptyl, 2,2-dimethylheptyl, 2-ethylheptyl, 2-butylheptyl, n-octyl, tert-octyl, 2-ethyloctyl, 2-butyloctyl, 2-hexyloctyl, 3,7-dimethyloctyl, cyclooctyl, n-nonyl, n-decyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldodecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-heneicosyl, n-docosyl, n-tricosyl, n-tetracosyl, n-pentacosyl, n-hexacosyl, n-heptacosyl, n-octacosyl, n-nonacosyl or n-triacontyl.

The term “chain hydrocarbyloxy” refers to a *—O-chain hydrocarbyl group, in which “*” denotes a linking site, and O denotes an oxygen atom. Suitable examples include, but are not limited to, methoxy (*—O—CH₃ or *-OMe), ethoxy (*—O—CH₂CH₃) or *-OEt), tert-butoxy (*—O—C(CH₃)₃ or *-OtBu), n-hexyloxy (*—O—C₆H₁₃), n-decyloxy (*—O—C₁₀H₂₁) or n-dodecyloxy (—O—C₁₂H₂₅).

The term “halogen group” refers to a *—X group, in which X denotes a halogen atom, for example, F, Cl, Br or I.

The term “cyclohydrocarbyl” refers to an aliphatic cyclohydrocarbyl group, and “a cyclohydrocarbyl group having 3 to 30 ring atoms” may, for example, have ring atoms of 3 to 5, 3 to 8, 1 to 10, 3 to 10, 3 to 14, 3 to 20, 5 to 10, 10 to 20, or 20 to 30, for example, 3, 5, 6, 8, 10, 14, 20, 24, 28, 30, or a value between any two of the foregoing values. Suitable examples include, but are not limited to, cyclopropyl, cyclobutyl, cyclopentyl, cyclohexyl, cycloheptyl, cyclooctyl, or adamantyl.

The term “aryl” refers to an aromatic hydrocarbyl group derived from an aromatic cyclic compound by removing a hydrogen atom, which may be a monocyclic aryl, or a fused ring aryl, or a polycyclic aryl in which at least one of the rings is an aromatic ring system. An “aryl having 6 to 30 ring atoms” may refer to an aryl group having 6 to 20 ring atoms, an aryl group having 6 to 18 ring atoms, an aryl group having 6 to 16 ring atoms, an aryl group having 6 to 14 ring atoms, or an aryl group having 6 to 10 ring atoms, in which the number of ring atoms may be, for example, 6, 10, 12, 14, 16, 18, 20, 24, 26, 28, 30, or a value between any two of the foregoing values. Suitable examples include, but are not limited to, phenyl, biphenyl, terphenyl, naphthyl, anthracenyl, phenanthrenyl, fluoranthenyl, triphenylenyl, pyrenyl, perylenyl, tetracenyl, fluorenyl, acenaphthylenyl, and derivatives thereof. It will be appreciated that a plurality of aryl groups may also be separated by short non-aromatic unit(s) (e.g., containing an amount of atoms less than 10% of total non-H atoms, such as C, N or O atoms). For example, acenaphthylene, fluorene, 9,9-diarylfluorene, triarylamine, diaryl ether systems are also be included in the definition of the aryl group.

The term “heteroaryl” refers to a group derived from an aryl group in which at least one carbon atom in the rings atoms is replaced by one or more non-carbon atoms selected from one or more of an N atom, an O atom, an S atom, a Si atom, or a P atom, and the number of the non-carbon atoms may be, for example, from 1 to 20. The “heteroaryl group having 5 to 30 ring atoms” may be a heteroaryl group having 5 to 20 ring atoms, a heteroaryl group having 5 to 18 ring atoms, a heteroaryl group having 5 to 16 ring atoms, a heteroaryl group having 5 to 14 ring atoms, a heteroaryl group having 5 to 12 ring atoms, or a heteroaryl group having 5 to 10 ring atoms. The number of ring atoms may be, for example, 5, 10, 12, 14, 18, 20, 24, 26, 28, 30, or a value between any two of the foregoing values. Suitable examples include, but are not limited to, thienyl, furanyl, pyrrolyl, diazolyl, triazolyl, imidazolyl, pyridyl, bipyridyl, pyrimidinyl, triazinyl, acridinyl, pyridazinyl, pyrazinyl, quinolinyl, isoquinolinyl, quinazolinyl, quinoxalinyl, phthalazinyl, pyridopyrimidinyl, pyridopyrazinyl, benzothienyl, benzofuranyl, indolyl, pyrroloimidazolyl, pyrrolopyrrolyl, thienopyrrolyl, thienothienyl, furopyrrolyl, furofuranyl, thienofuranyl, benzisoxazolyl, benzisothiazolyl, benzimidazolyl, cinnolinyl, phenanthridinyl, perimidinyl, quinazolinonyl, dibenzothienyl, dibenzofuranyl or carbazolyl.

The term “epoxy” refers to a

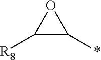

group, wherein R₈ is selected from hydrogen, deuterium, or a C1-C10 chain hydrocarbyl group.

Embodiments of the present disclosure provides a composition comprising, in parts by mass, 50 to 100 parts of a resin matrix, 20 to 100 parts of a multifunctional reactive monomer, 1 to 10 parts of an initiator, 5 to 30 parts of scattering particles, 100 to 500 parts of a solvent, and 1 to 10 parts of an adjuvant, wherein surfaces of the scattering particles are grafted with a modifying agent having a structure represented by the following general formula (I):

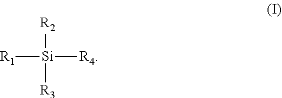

In the general formula (I), R₁ to R₃ are each independently selected from a C1-C30 alkoxy group, a halogen group,

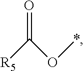

or a combination of thereof.

R₄ is selected from a C1-C30 chain hydrocarbyl group unsubstituted or substituted by at least one substituent, a cyclohydrocarbyl group having 3 to 30 ring atoms and unsubstituted or substituted by at least one substituent, an aryl group having 6 to 30 ring atoms and unsubstituted or substituted by at least one substituent, a heteroaryl group having 5 to 30 ring atoms and unsubstituted or substituted by at least one substituent, an epoxy group,

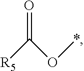

—NR₆R₇, or a combination thereof. The at least one substituent is at each occurrence selected from deuterium, a C1-C10 chain hydrocarbyl group, a C1-C10 chain hydrocarbyloxy group, a halogen group, a hydroxyl group, or a carboxyl group. R₅ is at each occurrence selected from a C1-C30 chain hydrocarbyl group. R₆ and R₇ are each independently selected from hydrogen, deuterium, a C1-C10 chain hydrocarbyl group, a C1-C10 chain hydrocarbyloxy group, an aryl group having 6 to 14 ring atoms, a heteroaryl group having 5 to 14 ring atoms, or a combination thereof.

In the composition of the embodiments of the present disclosure, the surfaces of the scattering particles are grafted with the modifying agent, so that the dispersion uniformity and the stability of the scattering particles in the resin matrix and the multifunctional reactive monomer are improved, and the “agglomeration” of the scattering particles is effectively prevented, thereby facilitating control of the particle size of the scattering particles, and imparting good scattering performance to the composition while improving the solution processing performance of the composition.

In some embodiments of the present disclosure, the modifying agent is selected from one or more of vinyltrichlorosilane (CAS No. 75-94-5), vinyltriethoxysilane (CAS No. 78-08-0), vinyltrimethoxysilane (CAS No. 2768-02-7), γ-aminopropyltriethoxysilane (CAS No. 919-30-2), γ-aminopropyltrimethoxysilane (CAS No. 13822-56-5), N-(β-aminoethyl)-γ-aminopropyltrimethoxysilane (CAS No. 1760-24-3), γ-(2,3-epoxypropoxy)propyltrimethoxysilane (CAS No. 2530-83-8), γ-(2,3-epoxypropoxy)propyltriethoxysilane (CAS No. 2602-34-8), γ-(methacryloxy)propyltrimethoxysilane (CAS No. 2530-85-0), γ-methacryloxypropyltrichlorosilane (CAS No. 7351-61-3), hexyltrimethoxysilane (CAS No. 16415-12-6), hexadecyltrimethoxysilane (CAS No. 16415-12-6), or octadecyltrimethoxysilane (CAS No. 3069-42-9).

In some embodiments of the present disclosure, the mass ratio of the scattering particles to the modifying agent grafted on the surfaces of the scattering particles is 1: (0.01 to 0.05), for example, 1:0.01, 1:0.02, 1:0.03, 1:0.04, 1:0.05, or a value between any two of the foregoing values. On the one hand, by setting the above mass ratio, the dispersion uniformity and stability of the scattering particles can be further improved, thereby improving the film-forming quality of the composition. On the other hand, the active sites located on the surfaces of the scattering particles can be sufficiently modified, while the mechanical properties of the film formed by the composition are improved, and the preparation cost is controlled.

In some embodiments of the present disclosure, a method of preparing a scattering particle grafted with a modifying agent includes the steps of providing a suspension including the scattering particles, and mixing and reacting the suspension and the modifying agent to obtain the scattering particles grafted and modified by the modifying agent. The dispersion medium of the suspension may be a C1-C10 alcohol compound, for example, one or more of methanol, ethanol, or propanol. The step of mixing and reacting the suspension and the modifying agent includes, for example, a step of mixing the suspension and a dispersion solution containing the modifying agent, in which the dispersion medium of the dispersion solution may be, for example, a mixture of a C1-C10 alcohol compound and water in a volume ratio of, for example, 9:1. The reacting may be a reflux reaction, at the temperature of, for example, 60° C. to 80° C., for, for example, 1 h to 5 h.

In order to improve the grafting modification effect of the modifying agent on the scattering particle, and to avoid excessive modification of the modifying agent leading to an increase in the production cost and a limited increase in the mechanical properties of the film formed by the composition, in some embodiments of the present disclosure, a mass ratio of the scattering particles to the modifying agent in the mixing and reacting is 1: (0.1 to 1), for example, 1:0.1, 1:0.3, 1:0.5, 1:0.8, 1:1, or a value between any two of the foregoing values.

In order to improve the purity of the surface-modified scattering particle, in some embodiments of the present disclosure, the method of preparing the scattering particles grafted and modified by the modifying agent further includes, after the step of the mixing and reacting and before the step of obtaining the surface-modified scattering particle, a step of subjecting the reaction product after reacting to solid-liquid separation, washing the collected solid, and then drying and grinding. The solid-liquid separation includes, but is not limited to, one or more of sedimentation, filtration, or evaporation. The sedimentation includes, but is not limited to, one or more of gravity sedimentation, centrifugal sedimentation, or electromagnetic force sedimentation. The filtration separation includes, but is not limited to, one or more of reverse osmosis, membrane filtration, nanofiltration, ultrafiltration, or microfiltration.

In order to ensure that the film layer formed from the composition has both a good scattering effect and a high transmittance, in some embodiments of the present disclosure, the refractive index of the scattering particle is 1.3 to 1.7, for example, 1.3, 1.35, 1.4, 1.5, 1.6, 1.7, or a value between any two of the foregoing values.

In some embodiments of the present disclosure, the scattering particles are selected from one or more of inorganic scattering particles or organic scattering particles. The inorganic scattering particles are selected from one or more of SiO₂, TiO₂, ZrO₂, Al₂O₃, or CaCO₃, and/or the organic scattering particles are selected from one or more of polystyrene, polymethyl methacrylate, or polybutyl methacrylate. The SiO₂ may be, for example, a gas-phase SiO₂.

In some embodiments of the present disclosure, the scattering particles are selected from spherical solid particles, or mesoporous particles formed by aggregation of nanoscale particles. The average particle size of the scattering particles and/or the aggregates of the scattering particles is 10 nm to 5 μm, for example, 10 nm, 50 nm, 100 nm, 1 μm, 3 μm, 5 μm, or a value between any two of the foregoing values.

In some embodiments of the present disclosure, the average particle size of the scattering particles and/or the aggregates of the scattering particles is 2 μm to 4 μm. On the one hand, the dispersion uniformity and the stability of the scattering particles can be further improved, thereby improving the film-forming quality of the composition. On the other hand, the film layer formed by the composition have a stronger scattering effect.

In order to further enhance the film-forming quality of the composition and improve the scattering effect of the film layer formed by the composition, in some embodiments of the present disclosure, the ratio of the mass of the scattering particles to the sum of the mass of the resin matrix, the multifunctional reactive monomer, the initiator, and the scattering particles is 15% to 23%, for example, 15%, 20%, 21%, 21.5%, 23%, or a value between any two of the foregoing value.

In the composition of the present embodiments, the resin matrix is used as a main skeleton component. In some embodiments of the present disclosure, the refractive index of the resin matrix is 1.3 to 1.7, for example, 1.3, 1.35, 1.4, 1.5, 1.6, 1.7, or a value between any two of the foregoing values. It is to be noted that the refractive index of the resin matrix may be close to the refractive index of the scattering particle. For example, the absolute value of the difference in refractive index between the resin matrix and the scattering particle is less than or equal to 0.1, thereby reducing the inner haze of the film layer formed by the composition.

In some embodiments of the present disclosure, the resin matrix is selected from one or more of acrylic resins, epoxy resins, or polyurethane resins.

In some embodiments of the present disclosure, the polymerization degree of the resin matrix is 10 to 100, for example, 10, 30, 50, 80, 100, or a value between any two of the foregoing values; and/or, the weight average molecular weight of the resin matrix is 1,000 to 30,000, for example, 1,000, 5,000, 10,000, 20,000, 30,000, or a value between any two of the foregoing values. It is to be noted that in order to improve the mechanical properties of the film layer formed by the composition, a cross-linked network structure is formedusing the resin matrix as the oligomer and the multifunctional reactive monomer. If the resin matrix in the composition is replaced with a cross-linked polymer, the solution processing is poor due to the fact that the cross-linked polymer has a high viscosity and is not easily soluble, resulting in poor film-forming quality.

Non-limiting examples of the resin matrix are shown in Table 1 below:

TABLE 1

| Name | Product model | Manufacturer |
|---|---|---|
| Polyurethane acrylate oligomer | CN996 NS | Sartomer (China) |
| | | Co., Ltd. |
| Polyester acrylate oligomer | CN2203 NS | Sartomer (China) |
| | | Co., Ltd. |
| Epoxy acrylate oligomer | CN2003 NS | Sartomer (China) |
| | | Co., Ltd. |
| Epoxy acrylate oligomer | CN115 NS | Sartomer (China) |
| | | Co., Ltd. |
| Polyurethane acrylate oligomer | CN968 NS | Sartomer (China) |
| | | Co., Ltd. |
| Polyurethane acrylate oligomer | UT53956 | Wraio Chemicals |
| Modified acrylic resin oligomer | UT95830 | Wraio Chemicals |
| Polyurethane acrylate oligomer | FSP59369 | Wraio Chemicals |
| Polyurethane acrylate oligomer | FSP2159 | Wraio Chemicals |
| Polyurethane acrylate oligomer | FSP56392 | Wraio Chemicals |

In some embodiments of the present disclosure, the multifunctional reactive monomer is selected from one or more of an acrylate monomer, an unsaturated olefin monomer, or an epoxy monomer.

Non-limiting examples of the multifunctional reactive monomer are shown in Table 2 below:

TABLE 2

| Name | CAS No. | Species |
|---|---|---|
| Dipentaerythritol hexaacrylate | 29570-58-9 | Acrylic monomer |
| Pentaerythritol triacrylate | 3524-68-3 | Acrylic monomer |
| Bis-trimethylolpropane tetraacrylate | 94108-97-1 | Acrylic monomer |
| Isobornyl acrylate | 5888-33-5 | Acrylic monomer |
| 1,6-hexanediol diacrylate | 13048-33-4 | Acrylic monomer |
| Dodecyl vinyl ether | 765-14-0 | Unsaturated olefin |
| | | monomer |
| Octadecyl vinyl ether | 930-02-9 | Unsaturated olefin |
| | | monomer |
| 1,4-cyclohexanedimethanol divinyl | 17351-75-6 | Unsaturated olefin |
| ether | | monomer |
| Dodecenyl succinic anhydride | 19780-11-1 | Unsaturated olefin |
| | | monomer |
| Triethylene glycol diglycidyl ether | 1954-28-5 | Epoxy monomer |
| Glycerol triglycidyl ether | 13236-02-7 | Epoxy monomer |
| Pentaerythritol tetraglycidyl ether | 3126-63-4 | Epoxy monomer |

In the composition of the embodiments of the present disclosure, the initiator is used to initiate the reaction of the resin matrix and the multifunctional reactive monomer under photo- and/or thermal conditions to form a cross-linked network structure. The initiator may be a common photoinitiator and/or thermal initiator, for example, one or more selected from a peroxide initiator, an azo initiator, an acylphosphine oxide photoinitiator, or an amine initiator.

In some embodiments of the present disclosure, the peroxide initiator is selected from one or more of dibenzoyl peroxide (CAS No. 94-36-0), lauroyl peroxide (CAS No. 105-74-8), tert-butyl peroxybenzoate (CAS No. 614-45-9), tert-butyl peroxypentanoate (CAS No. 927-07-1), or tert-hexyl peroxy(2-ethyl)hexanoate (CAS No. 137791-98-1), and/or the azo initiator is selected from one or more of azodiisobutyronitrile (CAS No. 78-67-1) and azodiisoheptanenitrile (CAS No. 4419-11-8), and/or the acylphosphine oxide photoinitiator is selected from one or more of 2,4,6-(trimethylbenzoyl)-diphenylphosphine oxide (CAS No. 75980-60-8) and phenylbis(2,4,6-trimethylbenzoyl)phosphine oxide (CAS No. 162881-26-7), and/or the amine initiator is selected from ethyl 4-dimethylaminobenzoate (CAS No. 10287-53-3).

In some embodiments of the present disclosure, the adjuvant is selected from one or more of a leveling agent, an antifoaming agent, a dispersant, an antifouling adjuvant, an antioxidant, or an ultraviolet absorber.

Non-limiting examples of the adjuvant are shown in Table 3 below:

TABLE 3

| Species | Product model | Manufacturer/brand |
|---|---|---|
| Leveling agent | SF-337 | Guangzhou Runao Chemical |
| | | Material Co., Ltd. |
| Leveling agent | SF-729 | Guangzhou Runao Chemical |
| | | Material Co., Ltd. |
| Leveling agent | BYK-300 | BYK |
| Antifoaming | SF-800 | Guangzhou Runao Chemical |
| | | Material Co., Ltd. |
| Dispersant | BYK-154 | BYK |
| Dispersant | BYK-W 903 | BYK |
| Dispersant | 7532 | AFCONA |
| Antifouling adjuvant | BYK-342 | BYK |
| Antifouling adjuvant | BYK-337 | BYK |
| Antifouling adjuvant | BYK-333 | BYK |
| Antioxidant | RIANOX 1010 | Tianjin Rianlon corporation |
| Antioxidant | RIANOX 1076 | Tianjin Rianlon corporation |
| Ultraviolet absorber | RIASORB UV-326 | Tianjin Rianlon corporation |
| Ultraviolet absorber | RIASORB UV-329 | Tianjin Rianlon corporation |

In some embodiments of the present disclosure, the solvent is selected from one or more of an ester compound, a ketone compound, an alcohol compound, or an ether compound. The ester compound has a general formula structure of R₉COOR₁₀, in which R₉ and R₁₀ are each independently selected from a C1-C10 alkyl group, a C1-C6 alkyl group, or a C1-C4 alkyl group. For example, the ester compound is selected from one or more of ethyl acetate, methyl acetate, ethyl formate, or propyl acetate. The ketone compound has a general formula structure of R₁₁COR₁₂, in which R₁₁ and R₁₂ are each independently selected from a C1-C10 alkyl group, a C1-C6 alkyl group, or a C1-C4 alkyl group. For example, the ketone compound is selected from one or more of acetone, methyl isobutyl ketone, or butyl ketone. The alcohol compound has a general formula structure of R₁₃OH, in which R₁₃ is selected from one or more of an unsubstituted C1-C10 alkyl group, a hydroxy-substituted C1-C10 alkyl group, an unsubstituted C1-C6 alkyl group, a hydroxy-substituted C1-C6 alkyl group, an unsubstituted C1-C4 alkyl group, or a hydroxy-substituted C1-C4 alkyl group. For example, the alcohol compound is selected from methanol, ethanol, propanol, butanol, or pentanol. The ether compound has a general formula structure of R₁₄OR₁₅, in which R₁₄ and R₁₅ are each independently selected from a C1-C10 alkyl group, a C1-C6 alkyl group, or a C1-C4 alkyl group. For example, the ether compound is selected from one or more of methyl ether, ethyl ether, propyl ether, butyl ether, or pentyl ether.

Embodiments of the present disclosure also provide a film obtained by subjecting any one composition as described above to a thermal curing treatment and/or a photocuring treatment. It will be appreciated that the material of the film includes a network structure formed by cross-linking of the resin matrix and the multifunctional reactive monomer.

In some embodiments of the present disclosure, as shown in FIG. 1, the film 1 includes a resin portion 11, and at least a portion of the scattering particles 12 protrude from the surface of the resin portion 11, so that the surface of the film 1 has a convex structure that can refract transmitted light so as to achieve a light mixing function. Here, the scattering particles 12 have a microsphere structure (as shown in FIG. 1(a)) or a mesoporous structure (as shown in FIG. 1(b)).

In some embodiments of the present disclosure, the average thickness of the film 1 is 1 μm to 10 μm, for example, 1 μm, 3 μm, 5 μm, 7 μm, 10 μm, or a value between any two of the foregoing values.

In some embodiments of the present disclosure, the mass of the scattering particles 12 constitutes 15% to 23%, for example, 15%, 18%, 20%, 21%, 22%, 23%, or a value between any two of the foregoing values, of the total mass of the film 1, to ensure that the film has a good scattering effect.

In some embodiments of the present disclosure, the method of preparing the film 1 includes, for example, the steps of providing a substrate, depositing the composition on a side of the substrate, and then subjecting the deposited composition to a thermal curing treatment and/or a photocuring treatment to obtain the film.

Herein, the deposition of the composition may be, for example, a solution method including, but not limited to, one or more of a spin coating method, a printing method, an inkjet printing method, a knife coating method, a dip-coating method, a soaking method, a spraying method, a roll coating method, a casting method, a slit coating method, or a strip coating method. The temperature of the thermal curing treatment may be, for example, 50° C. to 120° C. The photocuring treatment may be carried out, for example, by radiating of ultraviolet light.

Embodiments of the present disclosure further provide a display panel. Referring to FIGS. 2 to 4, the display panel 10 includes a light emitting element layer 101 and a wide view film 103. The light emitting element layer 101 includes an oppositely disposed light-input side 1016 and a light-output side 1011. The wide view film 103 includes a diffusion layer 1033 that is any one film as described above. The light emitting element layer 101 includes a plurality of pixels arranged in an array, each pixel including at least three sub-pixels with different primary colors. For example, each pixel consists of a red sub-pixel, a blue sub-pixel and a green sub-pixel.

In the display panel 10 according to the embodiments of the present disclosure, the film described in any one of the above can be used as the diffusion layer to improve the uniformity of the light rays of each viewing angle, ensure that the display panel has a good transmittance and resolution, effectively improve the chromaticity viewing angle of the display panel, prevent the problem of color deviation of a large viewing angle, and improve the picture quality felt by the human eye.

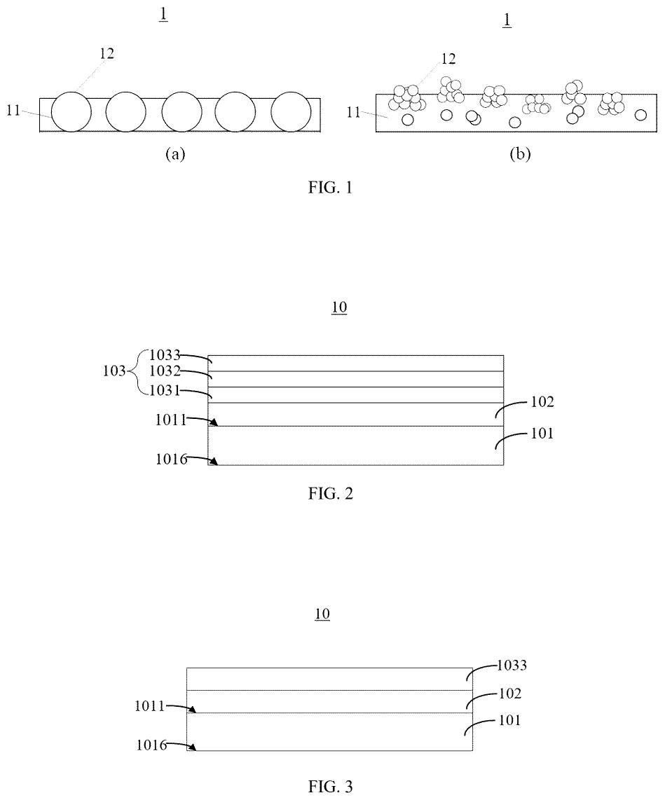

In some embodiments of the present disclosure, with continued reference to FIGS. 2 and 3, the display panel 10 further includes a first polarizer 102 disposed between the light emitting element layer 101 and the wide view film 103. The first polarizer may be of a conventional structure in the art, including, for example, an adhesive layer, a compensation film, a polarizing film, and a protection layer disposed in sequence, in which the adhesive layer is closer to the light emitting element layer 101 than the protection layer. A material of the adhesive layer includes but is not limited to one or more of a heat-sensitive adhesive, a pressure-sensitive adhesive, or an ultraviolet curable adhesive. A material of the compensation film includes but is not limited to one or more of polyethylene terephthalate (PET), tri-cellulose acetate (TCA), cyclic olefin polymer (COP), polycarbonate (PC), or polymethyl methacrylate (PMMA). A material of the polarizing film includes but is not limited to polyvinyl alcohol (PVA). A material of the protection layer includes but is not limited to one or more of PET, TCA, COP, or PMMA. The first polarizer 102 may also not include the compensation film.

In order to improve the mechanical properties of the wide view film 103, in at least one embodiment of the present disclosure, with continued reference to FIG. 2, the wide view film 103 further includes a base layer 1031 disposed on a side of the diffusion layer 1033 close to the light emitting element layer 101. A material of the base layer 1031 is selected from transparent polymers such as one or more of PET, TCA, COP, or PMMA. With continued reference to FIG. 2, the base layer 1031 may be bonded to a side of the light emitting element layer 101 by an adhesive layer 1032. A material of the adhesive layer 1032 includes, but is not limited to, one or more of a heat sensitive adhesive, a pressure sensitive adhesive, or an ultraviolet curable adhesive.

In order to simplify the manufacturing process of the display panel 10, in at least one embodiment of the present disclosure, with continued reference to FIG. 3, the wide view film 103 is the diffusion layer 1033.

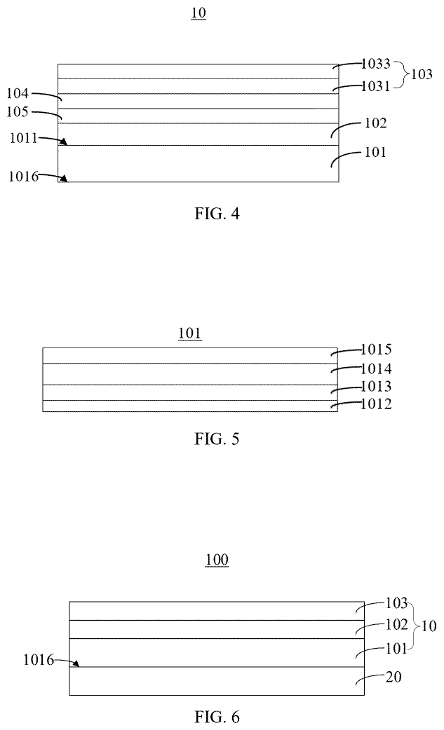

In still other embodiments of the present disclosure, with continued reference to FIG. 4, the display panel 10 further includes a polarizing film 104 and a compensation film 105 that are stacked. The polarizing film 104 is disposed between the light emitting element layer 101 and the wide view film 103. The compensation film 105 is disposed on a side of the polarizing film 104 away from the wide view film 103. The polarizing film 104 may be bonded to a side of the light emitting element layer 101 by one or more of a heat-sensitive adhesive, a pressure-sensitive adhesive, or an ultraviolet curable adhesive. In addition, the polarizing film 104 may be bonded to the compensation film 105 by one or more of a heat-sensitive adhesive, a pressure-sensitive adhesive, or an ultraviolet curable adhesive. The wide view film 103 includes, for example, the base layer 1031 and the diffusion layer 1033 that are stacked. The materials of the polarizing film 104 and the compensation film 105 may be described with reference to the foregoing.

In some embodiments of the present disclosure, referring to FIG. 5, the display panel is a liquid crystal display panel. The light emitting element layer 101 includes a second polarizer 1012, an array substrate 1013, a liquid crystal layer 1014, and a color film substrate 1015. The array substrate 1013 and the color film substrate 1015 are respectively disposed on opposite sides of the liquid crystal layer 1014. The second polarizer 1012 is disposed on a side of the array substrate 1013 away from the liquid crystal layer 1014. It is to be noted that the wide view film 103 is disposed on a side of the first polarizer 102 away from the color film substrate 1015. The structure composition of the second polarizer 1012 is described with reference to the first polarizer 102. The array substrate 1013, the liquid crystal layer 1014, and the color film substrate 1015 may be common structures in the art. The display mode of the liquid crystal display panel in the embodiments of the present disclosure includes, but is not limited to, twisted nematic (TN), in-plane-switching (IPS), or vertical alignment (VA).

In some embodiments of the present disclosure, the display panel has a multi-domain pixel structure, such as a four-domain pixel structure or an eight-domain pixel structure.

In other embodiments of the present disclosure, the light emitting element layer 101 includes a plurality of light emitting diodes arranged in an array, including, but not limited to, organic electroluminescent diodes or quantum dot light emitting diodes.

Embodiments of the present disclosure further provide a display device. As shown in FIG. 6, the display device 100 includes the display panel 10 described in any one of the above and a backlight source 20. The backlight source 20 is disposed on the light-input side 1016 of the light emitting element layer 101 in the display panel 10. The backlight source 20 may be a common structure composition in the art.

The display device includes, but is not limited to, a smartphone, a tablet computer, a mobile phone, a video phone, an electronic book reader, a laptop PC, a netbook computer, a workstation, a server, a personal digital assistant, a portable media player, an MP3 player, a mobile medical machine, a camera, a game machine, a digital camera, an in-vehicle navigator, an electronic billboard, an automatic teller machine, a smart band, a smart watch, a virtual reality (VR) device, or a wearable device.

The technical solutions and technical effects of the present disclosure will be described in detail by means of specific examples, comparative examples, and experimental examples. The following examples are merely partial examples of the present disclosure, and are not intended to specifically limit the present disclosure.

### Material Example 1

The present example provides a composition and a film, in which the composition includes, in parts by mass, 50 parts of a cross-linked polyacrylic resin oligomer (as a resin matrix), 50 parts of pentaerythritol triacrylate (as a polyfunctional reactive monomer), 5 parts of dibenzoyl peroxide (as an initiator), 12.1 parts of modified mesoporous SiO₂ particles (as scattering particles), 2 parts of an adjuvant (BYK-342, commercially available from BYK), 150 parts of ethyl acetate (as a solvent), and 150 parts of methyl isobutyl ketone (as a solvent, CAS No. 108-10-1). In the composition of the present example, the mass of the scattering particles was 10% of the sum of the mass of the resin matrix, the multifunctional reactive monomer, the initiator, and the scattering particles.

The cross-linked polyacrylic resin oligomer was purchased from Sadoma (China) Co., Ltd., in a product model of CN996 NS. The modified mesoporous SiO₂ particles were obtained by grafting mesoporous SiO₂ particles with γ-methacryloxypropyl trimethoxysilane (CAS No. 2530-85-0), in which a primary average particle size of the mesoporous SiO₂ particles was 15 nm, a average particle size of the aggregates of the mesoporous SiO₂ particles was 2 μm, the specific surface area of the mesoporous SiO₂ particles was 85 m²/g, and the adsorption DBA value of the mesoporous SiO₂ particles was 15 mmol/kg.

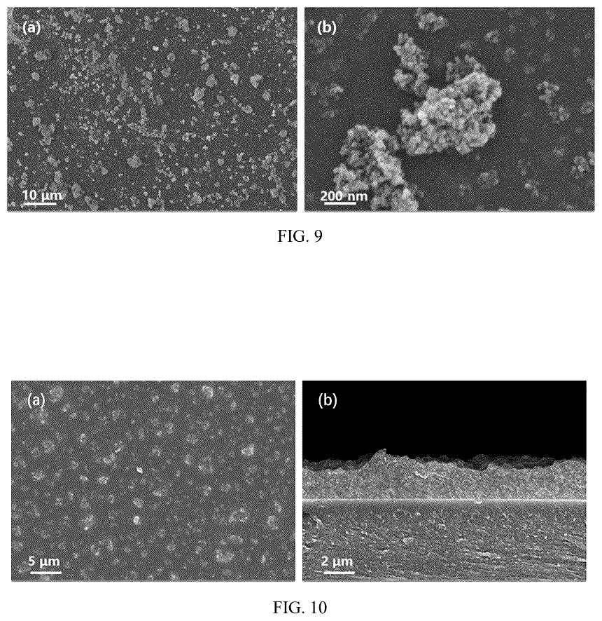

The preparation of the modified mesoporous SiO₂ particles includes the following steps:
S1.1. adding 10 g of mesoporous SiO₂ particles (powder) and 200 g of anhydrous ethanol to a 500 ml beaker and ultrasonically dispersing for 30 minutes to obtain a SiO₂ suspension;
S1.2. dissolving 5 g of γ-methacryloxypropyl trimethoxysilane in 100 g of an aqueous ethanol solution prepared by mixing ethanol and water at a mass ratio of 9:1, adding acetic acid to adjust the pH to 3 to 5, and stirring at normal temperature for 1 h to obtain a modifying agent dispersion solution;
S1.3. placing the SiO₂ suspension in step S1.1 in a 500 mL three-necked flask, adding the modifying agent dispersion solution in step S1.2 thereto, raising the temperature to 65° C., and stirring at reflux for 3 h to obtain a reaction solution;
S1.4. centrifuging the reaction solution obtained in step S1.3 at 10,000 r/min for 10 minutes, discarding the supernatant, adding ethanol, carrying out ultrasonic cleaning for 10 minutes, centrifuging again, and then repeating the above cleaning for three times, and drying and grinding the collected solid to obtain the modified mesoporous SiO₂ particles. The scanning electron microscope photograph of the modified mesoporous SiO₂ particles is shown in FIG. 9.

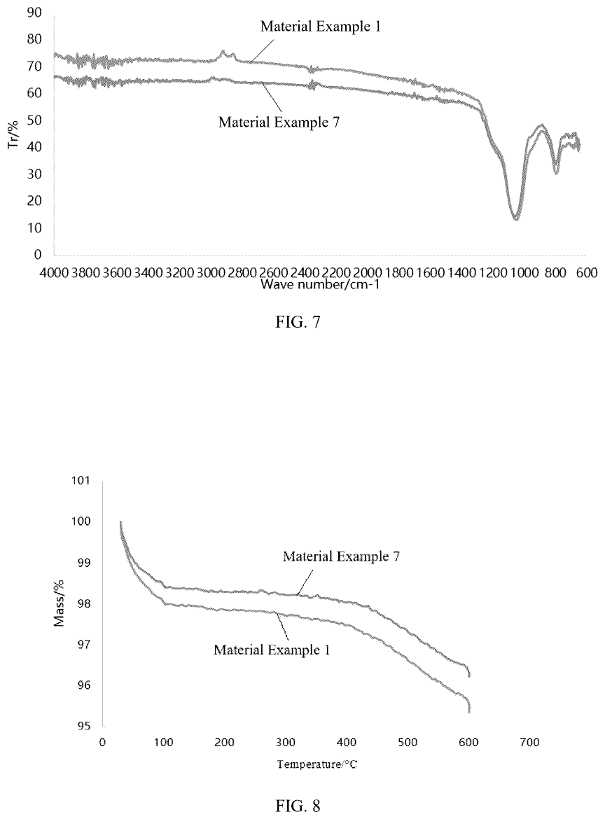

FIG. 7 shows an infrared spectrum of the modified mesoporous SiO₂ particles. After surface modification, the —OH ligand in-situ on the surface of the mesoporous SiO₂ particles is substituted by the modification group, and no Si—OH bending vibration absorption peak is present near 958 cm⁻¹, and absorption peaks appear only near 1090 cm⁻¹ and 800 cm⁻¹, which are Si—O—Si antisymmetric stretching vibration peak and Si—O symmetric stretching vibration peak, respectively.

FIG. 8 shows thermogravimetric analysis graphs of the modified mesoporous SiO₂ particles, in which the mass loss in stage \textcircled{1} (20° C. to 100° C.) is mainly caused by the volatilization of free water in the modified mesoporous SiO₂ particles, the mass loss in stage \textcircled{2} (100° C. to 300° C.) is mainly caused by the volatilization of bound water in the modified mesoporous SiO₂ particles, and the mass loss of stage \textcircled{3} (300° C. to 600° C.) is mainly caused by the decomposition of the modifying groups on the surface of the modified mesoporous SiO₂ particles. The mass ratio of the mesoporous SiO₂ particles to the γ-methacryloxypropyl trimethoxysilane grafted onto the surface of the mesoporous SiO₂ particles was calculated to be 1:0.02.

The film was prepared using the composition of the present embodiments, and the preparation of the film included the steps of providing a substrate, spin-coating the composition on a side of the substrate, and then curing the film by ultraviolet irradiation treatment in an irradiation intensity of 100 mW/cm² for 5 s to obtain a film having an average thickness of 3 μm.

### Material Example 2

The example provides a composition and a film, which were different from the composition in Material Example 1 in that the parts by mass of the modified mesoporous SiO₂ particles were replaced by “19.2 parts”, and the mass of the scattering particles in the composition of the present example was 15% of the sum of the mass of the resin matrix, the multifunctional reactive monomer, the initiator and the scattering particles.

The film in the present example was different from the film in Material Example 1 in that the film in the present example was prepared using the composition of the present example.

The preparation of the film in the present example was carried out with reference to the preparation of the film in Material Example 1.

### Material Example 3

The present example provides a composition and a film, which were different from the composition in the Material Example 1 in that the parts by mass of the modified mesoporous SiO₂ particles were replaced by “27.2 parts”, and, the mass of the scattering particles in the composition of the present example was 20% of the sum of the mass of the resin matrix, the multifunctional reactive monomer, the initiator, and the scattering particles.

The film in the present example was different from the film in Material Example 1 in that the film in the present example was prepared using the composition of the present example.

The preparation of the film in the present example was carried out with reference to the preparation of the film in Material Example 1.

### Material Example 4

The present example provides a composition and a film, which were different from the composition in the Material Example 1 in that the parts by mass of the modified mesoporous SiO₂ particles were replaced by “29.3 parts”, and the mass of the scattering particles in the composition of the present example was 21.5% of the sum of the mass of the resin matrix, the multifunctional reactive monomer, the initiator, and the scattering particles.

The film in the present example was different from the film in Material Example 1 in that the film in the present example was prepared using the composition of the present example.

The preparation of the film in the present example was carried out with reference to the preparation of the film in Material Example 1.

### Material Example 5

The present example provides a composition and a film, which were different from the composition in Material Example 1 in that the parts by mass of the modified mesoporous SiO₂ particles were replaced by “32 parts”, and the mass of the scattering particles in the composition of the present example was 23% of the sum of the mass of the resin matrix, the multifunctional reactive monomer, the initiator, and the scattering particles.

The film in the present example was different from the film in Material Example 1 in that the film in the present example was prepared using the composition of the present example.

The preparation of the film in the present example was carried out with reference to the preparation method of the film in Material Example 1.

### Material Example 6

The present example provides a composition and a film, which were different from the composition in the Material Example 1 in that the parts by mass of the modified mesoporous SiO₂ particles were replaced by “32.9 parts”, and the mass of the scattering particles in the composition of the present example was 23.5% of the sum of the mass of the resin matrix, the multifunctional reactive monomer, the initiator, and the scattering particles.

The film in the present example was different from the film in Material Example 1 in that the film in the present example was prepared using the composition of the present example.

The preparation of the film in the present example was carried out with reference to the preparation of the film in Material Example 1.

### Material Example 7

The present example provides a composition and a film, which were different from the composition in Material Example 1 in that the modified mesoporous SiO₂ particles were different. In the present example, the modified mesoporous SiO₂ particles were obtained by grafting mesoporous SiO₂ particles with γ-methacryloxypropyl trimethoxysilane (CAS No. 2530-85-0), in which the primary average particle size of the mesoporous SiO₂ particles was 15 nm, the average particle size of the aggregates of the mesoporous SiO₂ particles was 4 μm, the specific surface area of the mesoporous SiO₂ particles was 80 m²/g, and the adsorption DBA value of the mesoporous SiO₂ particles was 12 mmol/kg.

FIG. 7 shows the infrared spectrum of the modified mesoporous SiO₂ particles, and FIG. 8 shows the thermal weight loss curve of the modified mesoporous SiO₂ particles. The mass ratio of the mesoporous SiO₂ particles to the γ-methacryloxypropyl trimethoxysilane grafted onto the surface of the mesoporous SiO₂ particles was calculated to be 1:0.023.

The film in the present example was different from the film in Material Example 1 in that the film in the present example was prepared using the composition of the present example. FIG. 10(c) shows c scanning electron microscope photograph of the surface of the film, and FIG. 10(d) shows scanning electron microscope photograph of the cross section of the film.

The preparation of the film in the present example was carried out with reference to the preparation of the film in Material Example 1.

### Material Example 8

The present example provides a composition and a film, which were different from the composition in Material Example 1 in that the scattering particles were different. In the present example, the scattering particles were modified TiO₂ particles that were obtained by grafting TiO₂ nanoparticles with γ-methacryloxypropyl trimethoxysilane, in which the primary average particle size of the TiO₂ nanoparticles was 20 nm, and the average particle size of the aggregates of the TiO₂ nanoparticles was 2 μm. Specifically, the preparation of the modified TiO₂ particles in the present example was different from the preparation of the modified mesoporous SiO₂ particles in the Material Example 1 in that the “10 g of mesoporous SiO₂ particles (powder)” in step S1.1 was replaced with “10 g of TiO₂ nanoparticles”.

The film in the present example was different from the film in Material Example 1 in that the film in the present example was prepared using the composition of the present example.

The preparation of the film in the present example was carried out with reference to the preparation of the film in Material Example 1.

### Material Example 9

The present example provides a composition and a film, which were different from the composition in Material Example 1 in that the modified mesoporous SiO₂ particles were different. Specifically, the preparation of the modified mesoporous SiO₂ particles in the present example was different from the preparation of the modified mesoporous SiO₂ particles in the Material Example 1 in that the “5 g of γ-methacryloxypropyl trimethoxysilane” in step S1.2 was replaced with “2 g of γ-methacryloxypropyl trimethoxysilane”. The mass of the modified mesoporous SiO₂ particles in the present example was 10% of the total mass of the composition.

The film in the present example was different from the film in Material Example 1 in that the film in the present example was prepared using the composition of the present example.

The preparation of the film in the present example was carried out with reference to the preparation of the film in Material Example 1.

### Material Example 10

The present example provides a composition and a film, which were different from the composition in Material Example 1 in that the modified mesoporous SiO₂ particles were different. Specifically, the preparation of the modified mesoporous SiO₂ particles in the present example was different from the preparation of the modified mesoporous SiO₂ particles in Material Example 1 in that “5 g of γ-methacryloxypropyl trimethoxysilane” in Step S1.2 was replaced with “10 g of γ-methacryloxypropyl trimethoxysilane”. The mass of the modified mesoporous SiO₂ particles in the present example was 10% of the total mass of the composition.

The film in the present example was different from the film in Material Example 1 in that the film in the present example was prepared using the composition of the present example.

The preparation of the film in the present example was carried out with reference to the preparation of the film in Material Example 1.

### Material Example 11

The present example provides a composition and a film, which were different from the composition in Material Example 1 in that the modified mesoporous SiO₂ particles were different. Specifically, the preparation of the modified mesoporous SiO₂ particles in the present example was different from the preparation of the modified mesoporous SiO₂ particles in the Material Example 1 in that the “5 g of γ-methacryloxypropyl trimethoxysilane” in step S1.2 was replaced with “5 g of hexadecyltrimethoxysilane”.

The film in the present example was different from the film in Material Example 1 in that the film in the present example was prepared using the composition of the present example.

The preparation of the film in the present example was carried out with reference to the preparation of the film in Material Example 1.

### Material Example 12

The present example provides a composition and a film, which were different from the composition in Material Example 1 in that the scattering particles were different. In the present example, the scattering particles were modified SiO₂ microspheres that were obtained by grafting SiO₂ microspheres with γ-methacryloxypropyl trimethoxysilane, in which the average particle size of the SiO₂ microspheres was 2 μm. Specifically, the preparation of the modified SiO₂ microspheres in the present example was different from the preparation of the modified mesoporous SiO₂ particles in the Material Example 1 in that the “10 g of mesoporous SiO₂ particles (powder)” in step S1.1 was replaced with “10 g of SiO₂ microspheres”.

The film in the present example was different from the film in Material Example 1 in that the film in the present example was prepared using the composition of the present example.

The preparation of the film in the present example was carried out with reference to the preparation of the film in Material Example 1.

### Material Example 13

The present example provides a composition and a film, in which the composition includes, in parts by mass, 80 parts of a bisphenol A type epoxy resin (as a resin matrix), 20 parts of dodecenyl succinic anhydride (as an initiator), 12.1 parts of modified mesoporous SiO₂ particles (as scattering particles), 2 parts of an adjuvant (BYK-342, commercially available from BYK), 150 parts of ethyl acetate (as a solvent), and 150 parts of methyl isobutyl ketone (as a solvent, CAS number 108-10-1). In the composition of the present example, the mass of the scattering particles was 10% of the sum of the mass of the resin matrix, the multifunctional reactive monomer, the initiator, and the scattering particles.

The bisphenol A type epoxy resin was purchased from Shenzhen Jitian Chemical Co., Ltd., in a product model of E-128. The modified mesoporous SiO₂ particles were the same as in Material Example 1.

The film in the present example was different from the film in Material Example 1 in that the film in the present example was prepared using the composition of the present example.

The preparation of the film in the present example was carried out with reference to the preparation of the film in Material Example 1.

### Material Comparative Example

The present comparative example provides a composition and a film, which were different from the composition in Material Example 1 in that the scattering particles were different. In the present comparative example, the scattering particles were unmodified SiO₂ microspheres in an average particle size of 2 μm.

The film in this Comparative Example was different from the film in Material Example 1 in that the film in this Comparative Example was prepared using the composition of this Comparative Example.

The preparation of the film in the Comparative Example was carried out with reference to the preparation of the film in the Material Example 1.

### Display Device Example 1

The present example provides a display device. As shown in FIG. 6, the display device includes the display panel 10 and the backlight source 20. The backlight source 20 is disposed on the light-input side 1016 of the light emitting element layer 101 in the display panel 10. The backlight source 20 is a white backlight source.

The display panel 10 is a liquid crystal display panel. As shown in FIGS. 2 to 5, the display panel 10 includes the light emitting element layer 101, the first polarizer 102, and the wide view film 103 that are disposed in sequence. The light emitting element layer 101 includes the second polarizer 1012, the array substrate 1013, the liquid crystal layer 1014, and the color film substrate 1015 that are disposed in sequence. The light emitting element layer 101 includes a plurality of pixels arranged in an array, each pixel consisting of a red sub-pixel, a blue sub-pixel and a green sub-pixel.

The display panel of the present example is obtained by adding the wide view film 103 to a first standard display panel that has a four-domain pixel structure with a transmittance of 7%, a contrast ratio of 6,200:1, CESI 0.03 of 62°, 65 inches, and 4K resolution.

With continued reference to FIG. 2, the wide view film 103 includes the adhesive layer 1032, the base layer 1031, and the diffusion layer 1033 that are stacked in sequence. The material of the adhesive layer 1032 is a UV-curable adhesive, and the average thickness of the adhesive layer 1032 is 20 μm. The material of the base layer 1031 is polyethylene terephthalate, and the average thickness of the base layer 1031 is 60 μm. The material of the diffusion layer 1033 is a film obtained in the Material Example 1, and the average thickness of the diffusion layer 1033 is 3 μm.

### Display Device Example 2

The present example provides a display device that has a diffusion layer with different structures and compositions from the display device in Display Device Example 1. In the present example, the diffusion layer is a film obtained in Material Example 2. As in Display Device Example 1, the average thickness of the diffusion layer is 3 μm.

### Display Device Example 3

The present example provides a display device that has a diffusion layer with different structures and compositions from the display device in Display Device Example 1. In the example, the diffusion layer is a film obtained in Material Example 3. As in Display Device Example 1, the average thickness of the diffusion layer is 3 μm.

### Display Device Example 4

The present example provides a display device that has a diffusion layer with different structures and compositions from the display device in Display Device Example 1. In the present example, the diffusion layer is a film prepared in Material Example 4. As in Display Device Example 1, the average thickness of the diffusion layer is 3 μm.

### Display Device Example 5

The present example provides a display device has a diffusion layer with different structures and compositions from the display device in Display Device Example 1. In the example, the diffusion layer is a film obtained in Material Example 5. As in Display Device Example 1, the average thickness of the diffusion layer is 3 μm.

### Display Device Example 6

The example provides a display device that has a diffusion layer with different structures and compositions from the display device in Display Device Example 1. In the example, the diffusion layer is a film prepared in Material Example 6. As in Display Device Example 1, the average thickness of the diffusion layer is 3 μm.

### Display Device Example 7

The example provides a display device that has a diffusion layer with different structures and compositions from the display device in Display Device Example 1. In the example, the diffusion layer is a film prepared in Material Example 7. As in Display Device Example 1, the average thickness of the diffusion layer is 3 μm.

### Display Device Example 8

The example provides a display device that has a diffusion layer with different structures and compositions from the display device in Display Device Example 1. In the example, the diffusion layer is a film obtained in Material Example 8. As in Display Device Example 1, the average thickness of the diffusion layer is 3 μm.

### Display Device Example 9

The example provides a display device that has a diffusion layer with different structures and compositions from the display device in Display Device Example 1. In the example, the diffusion layer is a film obtained in Material Example 9. As in Display Device Example 1, the average thickness of the diffusion layer is 3 μm.

### Display Device Example 10

The example provides a display device that has a diffusion layer with different structures and compositions from the display device in Display Device Example 1. In the example, the diffusion layer is a film prepared in Material Example 10. As in Display Device Example 1, the average thickness of the diffusion layer is 3 μm.

### Display Device Example 11

The example provides a display device that has a diffusion layer with different structures and compositions from the display device in Display Device Example 1. In the example, the diffusion layer is a film obtained in Material Example 11. As in Display Device Example 1, the average thickness of the diffusion layer is 3 μm.

### Display Device Example 12

The example provides a display device that has a diffusion layer with different structures and compositions from the display device in Display Device Example 1. In the example, the diffusion layer is a film obtained in Material Example 12. As in Display Device Example 1, the average thickness of the diffusion layer is 3 μm.

### Display Device Example 13

The example provides a display device that has a diffusion layer with different structures and compositions from the display device in Display Device Example 1. In the example, the diffusion layer is a film obtained in Material Example 13. As in Display Device Example 1, the average thickness of the diffusion layer is 3 μm.

### Display Device Example 14

The example provides a display device that has a diffusion layer with different structures and compositions from the display device in Display Device Example 1. In the example, the diffusion layer is a film prepared from the composition in Material Example 3, and the average thickness of the diffusion layer is 2 μm.

### Display Device Example 15

The example provides a display device that has a diffusion layer with different structures and compositions from the display device in Display Device Example 1. In the example, the diffusion layer is a film prepared from the composition in Material Example 3, and the average thickness of the diffusion layer is 4 μm.

### Display Device Example 16

The example provides a display device that has a diffusion layer with different structures and compositions from the display device in Display Device Example 1. In the example, the diffusion layer is a film prepared from the composition in Material Example 3, and the average thickness of the diffusion layer is 5 μm.

### Display Device Example 17

The example provides a display device that is different from the display device in Display Device Example 1 in that the display device in the example is obtained by adding a wide view film to a second standard display device that has a driving circuit different from of that the first standard display device, with the transmittance of 5.3%, the contrast ratio of 5,000:1, the CESI 0.03 of 70°, 65 inches, and a resolution of 4K.

The structure and composition of the diffusion layer in the example is the same as the structure and composition of the diffusion layer in the Display Device Example 3.

### Display Device Comparative Example 1

The present comparative example provides a display device that has a diffusion layer with different structures and compositions from the display device in Display Device Example 1. In the present comparative example, the diffusion layer is a film obtained in the Material Comparative Example. As in Display Device Example 1, the average thickness of the diffusion layer is 3 μm.

### Display Device Comparative Example 2

The display panel provided in the comparative example is the first standard display device.

### Display Device Comparative Example 3

The display panel provided in the comparative example is the second standard display device.

### Display Device Comparative Example 4

The present comparative example provides a display device that is different from the the first standard display device in that the display panel of the display device in the present comparative example has an eight-domain pixel structure, a transmittance of 4.8%, a contrast ratio of 5,000:1, CESI 0.03 of 105°, 65 inches, and a resolution of 4K.

### Experimental Example 1

The mechanical properties of the films in Material Examples 1 to 13 and Material Comparative Example were tested for pencil hardness, wear resistance, and adhesion. The test for wear resistance was performed at #0000 steel wool, 400 g load, 10 cycles, and 60 cycles/min, and the test results were as shown in Table 4 below:

TABLE 4

| | Pencil | Wear | |
|---|---|---|---|
| No.: | hardness | resistance | Adhesion |
| Material Example 1 | 3H | Pass | 5B |
| Material Example 2 | 3H | Pass | 5B |
| Material Example 3 | 3H | Pass | 5B |
| Material Example 4 | 2H | Pass | 5B |
| Material Example 5 | 2H | Pass | 5B |
| Material Example 6 | 2H | Pass | 5B |
| Material Example 7 | 3H | Pass | 5B |
| Material Example 8 | 3H | Pass | 5B |
| Material Example 9 | 2H | Pass | 5B |
| Material Example 10 | 3H | Pass | 5B |
| Material Example 11 | 3H | Pass | 5B |
| Material Example 12 | 2H | Pass | 5B |
| Material Example 13 | 4H | Pass | 5B |
| Material | 2H | Pass | 5B |
| Comparative | | | |
| Example | | | |

As can be seen from Table 1, the films in Material Examples 1 to 13 and Material Comparative Example have good mechanical properties.

### Experimental Example 2

Under the same test conditions, the performances of the display devices in Display Device Examples 1 to 17 and Display Device Comparative Examples 1 to 4 were test.

The brightness of the display panel in the display device is measured using KONICA MINOLTA CS-2000 as a test instrument, including: placing the display device in a dark room, and measuring brightness in a normal direction parallel to the display panel to obtain the 255 grayscale image brightness of the display panel. The calculation equation of the transmittance is: transmittance (%)=255 grayscale image brightness of the display panel/brightness of the backlight source×100%. The calculation equation of the contrast ratio is: contrast ratio=255 grayscale image brightness of the display panel/0 grayscale brightness of the display panel.

The R/G/B grayscale values corresponding to nine feature color images in the test for CESI chromaticity viewing angle are shown as follows, in which R denotes a red component, G denotes a green component, and B denotes a blue component. The red image is R=166, G=62, and B=68; the blue image is R=64, G=69, and B=145; the dark-skinned image is R=115, G=87, and B=74; the light-skinned image is R=183, G=145, and B=128; the green image is R=76, G=143, and B=79; the yellow image is R=214, G=187, and B=43; the magenta image is R=177, G=690, and B=143; the cyan image is R=23, G=130, and B=154; and the gray image is R=121, G=121, and B=120. Tri-stimulus value XYZ in the CIE 1931 color space for each image is respectively measured, and testing is performed along the horizontal direction of the display panel and within an angle from −60° to +60° relative to the normal direction of the display panel. The tri-stimulus value XYZ is converted to the Lu′v′color space by the following conversion equation:

$${u}^{′} = \frac{4 X}{X + 15 Y + 3 Z}$$

$${v}^{′} = \frac{9 Y}{X + 15 Y + 3 Z}$$

Further, the color difference value at the angle is defined as

$$Δ uv = \sqrt{{( {u}^{′} - {u}_{0}^{′} )}^{2} + {( {v}^{′} - {v}_{0}^{′} )}^{2}} ,$$

in which u′0 and v′0 are the values of u′ and v′ when the measurement direction is 0 degree from the normal direction, respectively. CESI 0.03 is the angle at which the average of Δuv for the nine test images is 0.03.

In addition, the gloss and haze of the wide view films in the Display Device Examples 1 to 17 and the Display Device Comparative Example 1 are respectively detected. It is to be noted that the wide view film in each display device is detected separately, that is, the wide view film is not adhered to the surface of the first polarizer, and the detected the gloss and haze do not include the value of the gloss and haze of the first polarizer.

The haze of the wide view film is test with reference to the measurement of the haze of the transparent material in ISO 14782, using HAZE Meter/NDH 7000 (from NIPPON DENSHOKU) as the test instrument, so as to obtain the sum of the inner haze and the outer haze of the wide view film.

The gloss of the wide view film is measured at 60° using Multi Gloss 268A (from KONICA MINOLTA) as the test instrument.

TABLE 5

| | | | | Gloss of | | Brightness |
|---|---|---|---|---|---|---|
| | | | Chromaticity | wide view | Haze of | of display |
| | Transmittance | Contrast | viewing angle | film | wide view | panel |
| No. | (%) | ratio | (CESI 0.03) | (60°) | film | (Nit) |
| Display Device Example 1 | 6.84 | 4,613:1 | 72° | 16.7 | 48 | 420 |
| Display Device Example 2 | 6.62 | 4,012:1 | 76° | 12.4 | 66 | 407 |
| Display Device Example 3 | 6.37 | 3,331:1 | 84° | 7.3 | 78 | 391 |
| Display Device Example 4 | 6.12 | 2,257:1 | 92° | 6.8 | 83 | 376 |
| Display Device Example 5 | 6.01 | 1,850:1 | 110° | 6.3 | 88 | 369 |
| Display Device Example 6 | 5.91 | 1,650:1 | 120° | 5.8 | 89 | 363 |
| Display Device Example 7 | 6.53 | 3,956:1 | 76° | 19.2 | 65 | 401 |
| Display Device Example 8 | 5.99 | 1,755:1 | 82° | 12.1 | 73 | 368 |
| Display Device Example 9 | 6.65 | 5,145:1 | 66° | 28.5 | 38 | 409 |
| Display Device Example 10 | 6.78 | 4,402:1 | 72° | 15.6 | 50 | 416 |
| Display Device Example 11 | 6.81 | 4,587:1 | 72° | 16.2 | 48 | 418 |
| Display Device Example 12 | 6.45 | 5,325:1 | 66° | 46.7 | 22 | 396 |
| Display Device Example 13 | 6.51 | 4,344:1 | 70° | 17.7 | 46 | 400 |
| Display Device Example 14 | 6.45 | 3,875:1 | 80° | 8.6 | 74 | 396 |
| Display Device Example 15 | 6.04 | 2,120:1 | 92° | 6.9 | 82 | 371 |
| Display Device Example 16 | 5.94 | 2,455:1 | 88° | 7.0 | 80 | 365 |
| Display Device Example 17 | 5.15 | 3,500:1 | 100° | 7.3 | 84 | 316 |
| Display Device | 6.21 | 5,266:1 | 64° | 67.1 | 17 | 381 |
| Comparative Example 1 | | | | | | |
| Display Device | 7 | 6,200:1 | 62° | / | / | 430 |
| Comparative Example 2 | | | | | | |
| Display Device | 5.3 | 5,000:1 | 70° | / | / | 326 |
| Comparative Example 3 | | | | | | |
| Display Device | 4.8 | 4,000:1 | 95° | / | / | 295 |
| Comparative Example 4 | | | | | | |

As can be seen from Table 5, the overall performance of the display devices in the Display Device Examples 1 to 17 is superior to the display devices in the Display Device Comparative Examples 1 to 3. Although the display devices in the Display Device Comparative Examples 1 and 2 has a good transmittance, contrast ratio, and brightness, the chromaticity viewing angle thereof is lower than 65°, and the effect of improving color deviation is limited. The display device of the Display Device Comparative Example 3 has a chromaticity viewing angle of 70°, but the transmittance thereof is lower than 6%, and the optical performance is poor.

As can be seen from the performance data of the display devices in the Display Device Examples 1 to 17 and the Display Device Comparative Example 4, for, the film of the present disclosure used as a wide view film in a display panel having a four-domain pixel structure can improve the chromaticity deviation to reach a level comparable to the display panel having an eight-domain pixel structure. For example, the CESI 0.03 of the display panel in the Display Device Example 17 differs from the CESI 0.03 of the display panel in the Display Device Comparative Example 4 by only 5°, while maintaining a high transmittance. The manufacturing process of the display panel having the four-domain pixel structure is simpler and the manufacturing cost is lower than that of the display panel having the eight-domain pixel structure.

From the performance data of the Display Device Examples 1 and 7 and the Display Device Comparative Example 2, it can be seen that the values of CESI 0.03 of the display panels in the Display Device Examples 1 and 7 are raised by 10° and 17° as compared with the CESI 0.03 of the display panel in the Display Device Comparative Example 2, indicating that the scattering particles with a larger particle size exhibit lower gloss and higher haze due to a stronger scattering effect, thereby having a better chromaticity viewing angle.

As can be seen from the performance data of the display panels in the Display Device Examples 1 to 6 and the Display Device Comparative Example 2, when the content of scattering particles in the composition for preparing the wide view film is increased from 10% to 23.5%, the CESI 0.03 of the display panel is increased from 72° to 120°, with the amplitude of the increase from 10° to 58°. Due to the influence of scattering, the display panel in the bright state has partial light loss, and in the dark state has light leakage, so that the brightness and contrast ratio of the display panel are decreased.

From the performance data of the display panels in the Display Device Examples 1 and 14 to 16 and the Display Device Comparative Example 2, it can be seen that when the materials of the wide view film are the same, the average thickness of the wide view film has an effect on the CESI 0.03 of the display panel. When the average thickness of the wide view film is low, the number of scattering particles is small, the scattering degree is low, and the improvement in chromaticity viewing angle is low. As the average thickness of the wide view film increases, the number of scattering particles increases, the scattering degree increases, and the improvement in chromaticity viewing angle increases, and finally tends to stabilize.

In the above-mentioned embodiments, the description of each embodiment has its own emphasis, and parts not described in detail in a certain embodiment may refer to the related description of other embodiments.

The present disclosure has been described in detail with reference to the composition, the film, the display panel, and the display device provided in embodiments of the present disclosure. The principles and implementation of the present disclosure are described herein using specific examples. The description of the above embodiments is merely provided to help understand the technical solutions of the present disclosure and the core idea thereof. It will be appreciated by those of ordinary skill in the art that modifications may be made to the technical solutions described in the foregoing embodiments, or equivalent replacements may be made to some of the technical features therein. These modifications or replacements do not make the essence of the corresponding technical solutions deviate from the scope of the technical solutions of the present disclosure.

What is claimed is:

1. A composition comprising, in parts by mass:
50 to 100 parts of a resin matrix;
20 to 100 parts of a multifunctional reactive monomer;
1 to 10 parts of an initiator;
5 to 30 parts of scattering particles;
100 to 500 parts of a solvent; and
1 to 10 parts of an adjuvant;
wherein surfaces of the scattering particles are grafted with a modifying agent having a structure represented by a general formula (I): 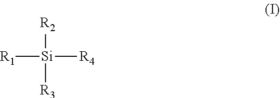
in the general formula (I), R₁ to R₃ are each independently selected from a C1-C30 alkoxy group, a halogen group, 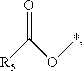
or a combination thereof,
R₄ is selected from a C1-C30 chain hydrocarbyl group unsubstituted or substituted by at least one substituent, a cyclohydrocarbyl group having 3 to 30 ring atoms and unsubstituted or substituted by at least one substituent, an aryl group having 6 to 30 ring atoms and unsubstituted or substituted by at least one substituent, a heteroaryl group having 5 to 30 ring atoms and unsubstituted or substituted by at least one substituent, an epoxy group, 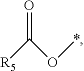
—NR₆R₇, or a combination thereof, wherein the at least one substituent is at each occurrence selected from deuterium, a C1-C10 chain hydrocarbyl group, a C1-C10 chain hydrocarbyloxy group, a halogen group, a hydroxyl group, or a carboxyl group;
R₅ is at each occurrence selected from a C1-C30 chain hydrocarbyl group; and
R₆ and R₇ are each independently selected from hydrogen, deuterium, a C1-C10 chain hydrocarbyl group, a C1-C10 chain hydrocarbyloxy group, an aryl group having 6 to 14 ring atoms, a heteroaryl group having 5 to 14 ring atoms, or a combination thereof.

2. The composition according to claim 1, wherein the modifying agent is selected from one or more of vinyltrichlorosilane, vinyltriethoxysilane, vinyltrimethoxysilane, γ-aminopropyltriethoxysilane, γ-aminopropyltrimethoxysilane, N-(β-aminoethyl)-γ-aminopropyltrimethoxysilane, γ-(2,3-epoxypropoxy)propyltrimethoxysilane, γ-(2,3-epoxypropoxy)propyltriethoxysilane, γ-(methacryloxy)propyltrimethoxysilane, γ-methacryloxypropyltrichlorosilane, hexyltrimethoxysilane, hexadecyltrimethoxysilane, or octadecyltrimethoxysilane.

3. The composition according to claim 1, wherein at least one of the following is satisfied:
a mass ratio of the scattering particles to the modifying agent grafted on the surfaces of the scattering particles is 1: (0.01 to 0.05);
a mass ratio of the scattering particles is 15% to 23% based on a sum of a mass of the resin matrix, a mass of the multifunctional reactive monomer, a mass of the initiator, and the mass of the scattering particles;
a refractive index of the scattering particles is 1.3 to 1.7;
the scattering particles are selected from spherical solid particles or mesoporous particles; or
an average particle size of the scattering particles and/or aggregates of the scattering particles is 10 nm to 5 μm.

4. The composition according to claim 3, wherein the average particle size of the scattering particles and/or the aggregates of the scattering particles is 2 μm to 4 μm.

5. The composition according to claim 3, wherein the scattering particles are selected from one or more of inorganic scattering particles or organic scattering particles,
wherein the inorganic scattering particles are selected from one or more of SiO₂, TiO₂, ZrO₂, Al₂O₃, or CaCO₃, and
the organic scattering particles are selected from one or more of polystyrene, polymethyl methacrylate, or polybutyl methacrylate.

6. The composition according to claim 1, wherein the resin matrix is selected from one or more of acrylic resin, epoxy resin, or polyurethane resin.

7. The composition according to claim 6, wherein at least one of the following is satisfied:
a refractive index of the resin matrix is 1.3 to 1.7;
a polymerization degree of the resin matrix is 10 to 100; or
a weight average molecular weight of the resin matrix is 1,000 to 30,000.

8. The composition according to claim 1, wherein
the multifunctional reactive monomer is selected from one or more of an acrylate monomer, an unsaturated olefin monomer, or an epoxy monomer;
the initiator is selected from one or more of a peroxide initiator, an azo initiator, an acylphosphine oxide photoinitiator, or an amine initiator;
the solvent is selected from one or more of an ester compound, a ketone compound, an alcohol compound, or an ether compound; and
the adjuvant is selected from one or more of a leveling agent, an antifoaming agent, a dispersant, an antifouling adjuvant, an antioxidant, or an ultraviolet absorber.

9. The composition according to claim 8, wherein the acrylate monomer is selected from one or more of pentaerythritol triacrylate, dipentaerythritol hexaacrylate, bis-trimethylolpropane tetraacrylate, isobornyl acrylate, or 1,6-hexanediol diacrylate;
the unsaturated olefin monomer is selected from one or more of dodecenyl succinic anhydride, dodecyl vinyl ether, octadecyl vinyl ether, or 1,4-cyclohexanedimethanol divinyl ether,
the epoxy monomer is selected from one or more of triethylene glycol diglycidyl ether, glycerol triglycidyl ether, or pentaerythritol tetraglycidyl ether;
the peroxide initiator is selected from one or more of dibenzoyl peroxide, lauroyl peroxide, tert-butyl peroxybenzoate, tert-butyl peroxypentanoate, or tert-hexyl peroxy(2-ethyl)hexanoate,
the azo initiator is selected from one or more of azodiisobutyronitrile or azodiisoheptanenitrile,
the acylphosphine oxide photoinitiator is selected from one or more of 2,4,6-(trimethylbenzoyl)-diphenylphosphine oxide or phenylbis(2,4,6-trimethylbenzoyl)phosphine oxide,
the amine initiator is selected from ethyl 4-dimethylaminobenzoate;
the ester compound is selected from one or more of ethyl acetate, methyl acetate, ethyl formate, or propyl acetate,
the ketone compound is selected from one or more of acetone, methyl isobutyl ketone, or butyl ketone,
the alcohol compound is selected from one or more of methanol, ethanol, propanol, butanol, or pentanol, and
the ether compound is selected from one or more of methyl ether, ethyl ether, propyl ether, butyl ether, or pentyl ether.

10. A display panel, comprising:
a light-emitting element layer having a light-input side and a light-output side opposite to each other; and
a wide view film disposed on the light-output side of the light emitting element layer;
wherein the wide view film comprises a diffusion layer obtained as a film by performing a thermal curing treatment and/or a photocuring treatment of a composition, wherein the composition comprises, in parts by mass:
50 to 100 parts of a resin matrix;
20 to 100 parts of a multifunctional reactive monomer;
1 to 10 parts of an initiator;
5 to 30 parts of scattering particles;
100 to 500 parts of a solvent; and
1 to 10 parts of an adjuvant;
wherein surfaces of the scattering particles are grafted with a modifying agent having a structure represented by a general formula (I): 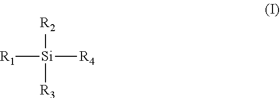
in the general formula (I), R₁ to R₃ are each independently selected from a C1-C30 alkoxy group, a halogen group, 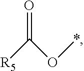
or a combination thereof;
R₄ is selected from a C1-C30 chain hydrocarbyl group unsubstituted or substituted by at least one substituent, a cyclohydrocarbyl group having 3 to 30 ring atoms and unsubstituted or substituted by at least one substituent, an aryl group having 6 to 30 ring atoms and unsubstituted or substituted by at least one substituent, a heteroaryl group having 5 to 30 ring atoms and unsubstituted or substituted by at least one substituent, an epoxy group, 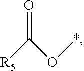
—NR₆R₇, or a combination thereof,
wherein the at least one substituent is at each occurrence selected from deuterium, a C1-C10 chain hydrocarbyl group, a C1-C10 chain hydrocarbyloxy group, a halogen group, a hydroxyl group, or a carboxyl group;
R₅ is at each occurrence selected from a C1-C30 chain hydrocarbyl group; and
R₆ and R₇ are each independently selected from hydrogen, deuterium, a C1-C10 chain hydrocarbyl group, a C1-C10 chain hydrocarbyloxy group, an aryl group having 6 to 14 ring atoms, a heteroaryl group having 5 to 14 ring atoms, or a combination thereof.

11. The display panel according to claim 10, wherein the film comprises a resin portion, and at least a portion of the scattering particles protrude from a surface of the resin portion.

12. The display panel according to claim 10, wherein at least one of the following is satisfied:
an average thickness of the film is 1 μm to 10 μm; or
a mass ratio of the scattering particles is 15% to 23% based on a total mass of the film.

13. The display panel according to claim 10, wherein the display panel comprises a first polarizer disposed between the light emitting element layer and the wide view film.

14. The display panel according to claim 13, wherein the display panel comprises a polarizing film and a compensation film stacked between the first polarizer and the wide view film, and
the polarizing film is disposed close to the wide view film, and the compensation film is disposed on a side of the polarizing film away from the wide view film.

15. The display panel according to claim 10, wherein the wide view film comprises a base layer disposed on a side of the diffusion layer close to the light emitting element layer, and
the base layer is selected from a transparent polymer selected from one or more of ethylene benzenedicarboxylate, polymethyl methacrylate, cellulose triacetate, or a cyclic olefin polymer.

16. The display panel according to claim 10, wherein the light emitting element layer comprises a second polarizer, an array substrate, a liquid crystal layer, and a color film substrate that are stacked in sequence, and
the wide view film is disposed on a side of the color film substrate away from the liquid crystal layer.

17. The display panel according to claim 10, wherein the light emitting element layer comprises a plurality of light emitting diodes arranged in an array.

18. The display panel according to claim 10, wherein the display panel has a multi-domain pixel structure.

19. The display panel according to claim 18, wherein the display panel has a four-domain pixel structure or an eight-domain pixel structure.

20. A display device comprising:
a display panel comprising:
a light emitting element layer having a light-input side and a light-output side opposite to each other; and
a wide view film disposed at the light-output side of the light emitting element layer;
a backlight source disposed at the light-input side of the light emitting element layer in the display panel,
wherein the wide view film comprises a diffusion layer obtained as a film by performing a thermal curing treatment and/or a photocuring treatment of a composition, and
the composition comprises, in parts by mass:
50 to 100 parts of a resin matrix;
20 to 100 parts of a multifunctional reactive monomer;
1 to 10 parts of an initiator;
5 to 30 parts of scattering particles;
100 to 500 parts of a solvent; and
1 to 10 parts of an adjuvant;
wherein surfaces of the scattering particles are grafted with a modifying agent having a structure represented by a general formula (I): 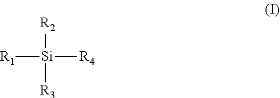
in the general formula (I), R₁ to R₃ are each independently selected from a C1-C30 alkoxy group, a halogen group, 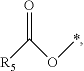
or a combination thereof; and
R₄ is selected from a C1-C30 chain hydrocarbyl group unsubstituted or substituted by at least one substituent, a cyclohydrocarbyl group having 3 to 30 ring atoms and unsubstituted or substituted by at least one substituent, an aryl group having 6 to 30 ring atoms and unsubstituted or substituted by at least one substituent, a heteroaryl group having 5 to 30 ring atoms and unsubstituted or substituted by at least one substituent, an epoxy group, 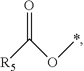
—NR₆R₇, or a combination thereof,
wherein the at least one substituent is at each occurrence selected from deuterium, a C1-C10 chain hydrocarbyl group, a C1-C10 chain hydrocarbyloxy group, a halogen group, a hydroxyl group, or a carboxyl group; R₅ is at each occurrence selected from a C1-C30 chain hydrocarbyl group; and R₆ and R₇ are each independently selected from hydrogen, deuterium, a C1-C10 chain hydrocarbyl group, a C1-C10 chain hydrocarbyloxy group, an aryl group having 6 to 14 ring atoms, a heteroaryl group having 5 to 14 ring atoms, or a combination thereof.
